(19) United States
(12) Patent Application Publication
(10) Pub. No.: US 2018/0374983 A1
(43) Pub. Date: Dec. 27, 2018

(54) METHOD OF MANUFACTURING A SPAD CELL

(71) Applicant: STMicroelectronics (Crolles 2) SAS, Crolles (FR)

(72) Inventors: Dominique GOLANSKI, Gieres (FR); Jean JIMENEZ, Salles d'Aude (FR); Didier DUTARTRE, Meylan (FR); Olivier GONNARD, Saint-Egreve (FR)

(73) Assignee: STMicroelectronics (Crolles 2) SAS, Crolles (FR)

(21) Appl. No.: 16/008,613

(22) Filed: Jun. 14, 2018

(30) Foreign Application Priority Data
Jun. 21, 2017 (FR) 1755669

(51) Int. Cl. H01L 31/18; H01L 31/107; H01L 29/66; H01L 21/265

(52) U.S. Cl. CPC H01L 31/18; H01L 21/265; H01L 29/66477; H01L 31/107

(57) ABSTRACT

A method for manufacturing a SPAD photodiode starts with the delimitation of a formation area for the SPAD photodiode in a layer of semiconductor material that is doped with a first dopant type. Dopant of a second dopant type is implanted in the layer of semiconductor material to form a buried region within the formation area. An epitaxial layer is then grown on the layer of semiconductor material at least over the formation area. MOS transistors are then formed on and in the epitaxial layer at locations outside of the formation area.

### PRIORITY CLAIM

This application claims the priority benefit of French Application for Patent No. 1755669, filed on Jun. 21, 2017, the disclosure of which is hereby incorporated by reference in its entirety to the maximum extent allowable by law.

### TECHNICAL FIELD

The present application relates to the field of avalanche photodiodes for the detection of single photons, also called SPAD (“Single Photon Avalanche Diode”) photodiodes and more particularly their method of manufacturing.

### BACKGROUND

A SPAD photodiode essentially consists of a reverse-biased PN junction at a voltage higher than its avalanche threshold. When no electrical charge is present in the depletion area or space charge area of the PN junction, the photodiode is in a pseudo-stable non-conductive state. When a photogenerated electrical charge is injected into the depletion area, if the displacement speed of this charge in the depletion area is sufficiently high, i.e. if the electrical field in the depletion area is sufficiently intense, the photodiode is likely to enter avalanche. A single photon is thus capable of generating a measurable electrical signal with a very short response time. SPAD photodiodes make it possible to detect radiation of very low light intensity, and are notably used for detecting single photons and counting photons.

It would be desirable to be able to at least partly improve some aspects of the methods of manufacturing known SPAD photodiodes.

### SUMMARY

Thus, one embodiment provides a method of manufacturing a SPAD photodiode, compatible with the manufacturing of MOS transistors, including: delimiting a formation area of a SPAD photodiode in a layer of semiconductor material of a first type of doping; implanting dopants of a second type with a first energy in a first buried region of said area; and growing an epitaxial layer over the entire structure.

According to one embodiment, the method of manufacturing further includes: forming one or more MOS transistors outside of said formation area.

According to one embodiment, the formation of one or more MOS transistors includes: implanting dopants of a second type of doping with a second energy, the second energy being greater than the first energy.

According to one embodiment, the first energy is of the order of 100 keV and the second energy is substantially between 1 and 1.4 MeV.

According to one embodiment, the first type of doping is P-type and the second type of doping is N-type.

According to one embodiment, the first buried region lies at a depth of between 50 and 500 nm with respect to the surface of the layer of semiconductor material, before the epitaxial growth step.

According to one embodiment, the formation area of the SPAD cell is delimited by cavities etched into the substrate around the formation area of the SPAD cell.

According to one embodiment, the epitaxial layer has a thickness of between 1 and 2 μm.

### BRIEF DESCRIPTION OF THE DRAWINGS

These features and advantages, as well as others, will be disclosed in detail in the following non-restrictive description of particular embodiments given in relation to the accompanying figures in which:

FIG. 1 is a cross-sectional view illustrating a step in manufacturing MOS transistors;

FIGS. 2A to 2D are cross-sectional views illustrating steps of an embodiment of a method of manufacturing a SPAD photodiode; and

FIG. 3 is a cross-sectional view of a structure suited to the formation of a SPAD photodiode and a MOS transistor.

### DETAILED DESCRIPTION

The same elements have been designated by the same references in the different figures and, in addition, the various figures are not drawn to scale. For the sake of clarity, only the elements useful to the understanding of the embodiments described have been represented and are given in detail. In particular, the various connections such as the cathode and anode connections of the SPAD photodiode are not represented.

In the description that follows, when reference is made to qualifiers such as the terms “left”, “right”, “above”, or “upper” this refers to the orientation of the elements concerned in the figures. Unless otherwise specified, the terms “substantially” and “of the order of” mean within 30%.

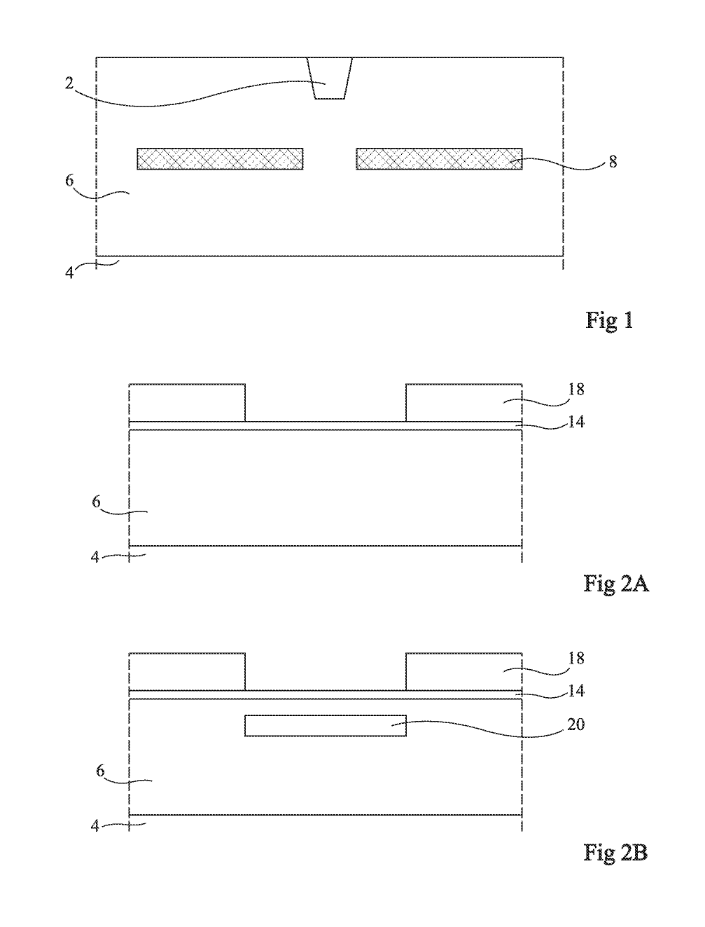

FIG. 1 is a cross-sectional view illustrating a step in a common method of manufacturing MOS transistors.

The structure in FIG. 1 is divided into two portions, right and left, similarly formed and separated by an isolating trench 2 of the STI (“Shallow Trench Isolation”) type. The two portions correspond to identical conventional structures on and in which MOS transistors may be formed. Each structure is formed on the same substrate 4, e.g. made of P-type heavily doped silicon on which an epitaxial layer 6 of P-type more lightly doped silicon rests.

Each structure includes an N-type doped region 8 deeply buried in the layer 6 at a depth substantially between 1 and 3 μm from a top surface of the layer 6. This region 8 has been formed by deep high energy implantation, e.g. by an implantation of phosphorus carried out at an energy substantially between 1 and 1.4 MeV.

These structures would able to allow the formation of SPAD photodiodes the cathode of which, connected in a manner not represented, would correspond to the buried region 8 and the anode of which would correspond to the portion of the layer 6 located above this buried layer 8. The implantation depth of the region 8 would suit a photodiode operating in the visible and near infrared domain. It would then be possible to simultaneously form SPAD photodiodes and MOS transistors in and on neighboring structures such as the two structures illustrated in FIG. 1.

However, although such a structure is well suited to the operation of MOS transistors, a SPAD photodiode formed from a similar structure encounters various problems. Notably, it has a significant dark noise.

It would be desirable to provide a method of manufacturing neighboring SPAD photodiodes of MOS transistors at least partially remedying the problems described previously.

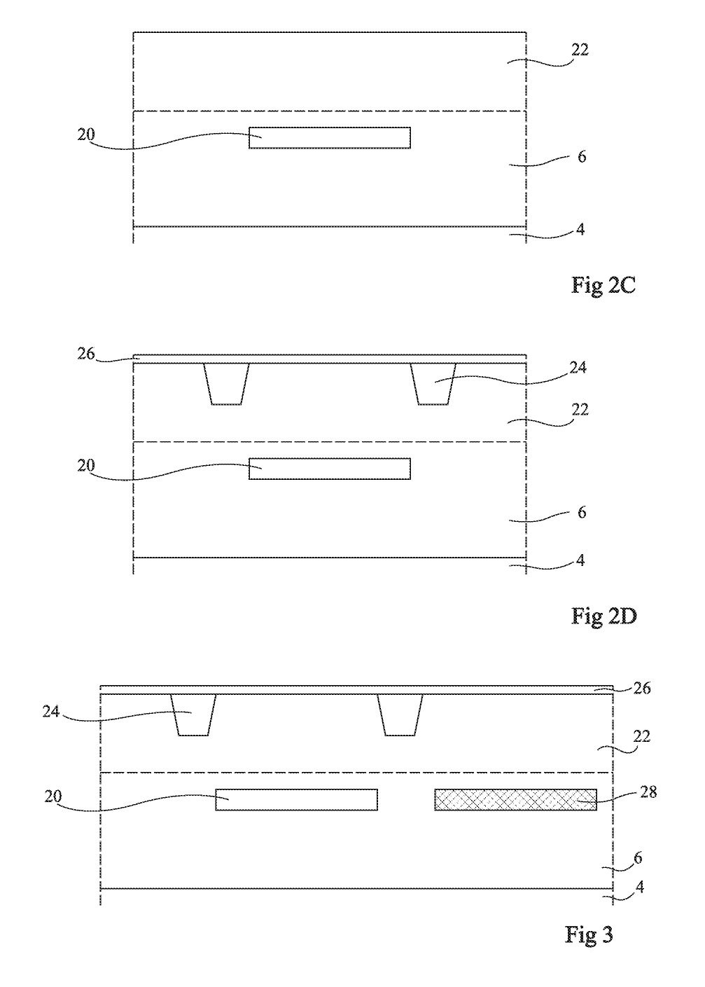

FIGS. 2A to 2D are sectional views illustrating steps of an embodiment of a method of manufacturing a SPAD photodiode.

FIG. 2A illustrates an initial step of manufacturing. This step is performed on a P-type heavily doped semiconductor substrate 4 covered with a P-type less doped layer 6. The layer 6 formed, for example, by epitaxy has, for example, a thickness of between 3 and 5 μm, e.g. 4 μm. The substrate 4 and the layer 6 are, for example, made of monocrystalline silicon.

SPAD photodiode formation areas are, for example, identified by alignment marks not represented in the figures. These alignment marks are, for example, hollowed out cavities around the formation areas.

In the course of this initial step, a layer 14 of insulator, e.g. made of silicon oxide, is formed on the substrate. A mask 18 is formed on the layer 14 of insulator. The mask 18 includes an opening situated opposite the site provided for the SPAD photodiode.

In the step illustrated in FIG. 2B, an implantation is carried out so as to form an N-type doped region 20 buried in the semiconductor layer 6 opposite the opening of the mask 18. A first anneal is then preferably carried out.

The region 20 has a thickness of between 0.3 and 0.7 μm, e.g. 0.5 μm. The region 20 is buried in the layer 6 at a depth, for example, of between 50 and 500 nm. Because of this shallow depth, the implantation is done with a low energy, e.g. substantially equal to 100 keV.

In the step illustrated in FIG. 2C, the masking layer 18 and the layer of insulator 14 are removed and a P-type doped silicon layer 22 is formed by epitaxial growth on the semiconductor layer 6. The boundary between the semiconductor layer 6 and the silicon layer 22 is represented by a dotted line. The concentration of dopant atoms in the silicon layer 22 is, for example, between 10¹⁴ and 10¹⁶ atoms/cm³. The thickness of this silicon layer 22 is chosen taking into account the operating wavelength of the SPAD photodiode. For a wavelength in the visible or the near infrared spectrum, e.g. between 0.5 and 2 μm, the thickness of the epitaxial layer is, for example, between 1 and 2 μm.

In the step illustrated in FIG. 2D, isolating trenches 24 of the STI-type are formed around the SPAD photodiode. The structure is then generally covered with a layer 26 of insulator, e.g. silicon oxide.

The structure is completed by a connection, not represented, with the region 20, as well as various other connections with elements of the photodiode.

Various dopant implantations may be carried out subsequently so as to adjust the doping profiles or levels of the junction between the implanted region 20 and the upper P-type doped region.

The SPAD photodiode resulting from the method described in relation to FIGS. 2A to 2E has substantially less dark noise than the SPAD photodiode described in relation to FIG. 1. This can be attributed to the absence of high energy implantation. Indeed, high energy implantations cause the formation of crystal defects which do not affect MOS transistors but which harm the performance of SPAD photodiodes.

In FIG. 3, the left-hand portion corresponds to the structure illustrated in FIG. 2D and the right-hand portion corresponds to a neighboring structure where a MOS transistor will be formed. The structure of the right-hand portion includes an N-type doped region 28 buried in the layer 6 and the silicon layer 22 formed by epitaxial growth in the course of the step illustrated in FIG. 2C.

It is possible to form the region 28 in the course of the step illustrated in FIG. 2B, during the formation of the region 20. It is also possible to form the region 28 by the common method, i.e. by a deep high energy implantation after the epitaxial growth of the layer 22. This makes it possible to slightly modify the common methods of manufacturing MOS transistors.

One particular embodiment has been described. Various variants and modifications will be apparent to the person skilled in the art. In particular, the dopants, the levels of doping and the thickness of the epitaxial layer 22 may vary according to the SPAD photodiode to be manufactured.

1. A method of manufacturing a SPAD photodiode, compatible with the manufacturing of MOS transistors, including:
delimiting a formation area of a SPAD photodiode in a layer of semiconductor material doped with dopants of a first dopant type;
implanting a dopant of a second dopant type with a first energy in said layer of semiconductor material to form a first buried region of said formation area; and
growing an epitaxial layer on a top surface of the layer of semiconductor material above at least the first buried region.

2. The method of manufacturing according to claim 1, further including:
forming one or more MOS transistors on and in said epitaxial layer at a location outside of said formation area.

3. The method according to claim 2, wherein forming one or more MOS transistors comprises:
implanting a dopant of a second dopant type with a second energy, wherein the second energy is greater than the first energy.

4. The method according to claim 3, wherein the first energy is on the order of 100 keV and the second energy is substantially between 1 and 1.4 MeV.

5. The method according to claim 1, in which the first dopant type is P-type and the second dopant type is N-type.

6. The method according to claim 1, wherein the first buried region lies at a depth of between 50 and 500 nm with respect to the top surface of the layer of semiconductor material, and the epitaxial layer has a thickness of between 1 and 2 μm.

7. The method according to claim 1, wherein which the formation area of the SPAD cell is delimited by cavities etched into the substrate around the formation area of the SPAD cell.

8. The method according to claim 1, wherein the epitaxial layer has a thickness of between 1 and 2 μm.
